(19) United States
(12) Patent Application Publication
(10) Pub. No.: US 2006/0151428 A1
(43) Pub. Date: Jul. 13, 2006

(54) Method for roughening a surface of a body, and optoelectronic component

(76) Inventors: Reiner Windisch, Pettendorf (DE); Ralph Wirth, Pettendorf-Adlersberg (DE); Heribert Zull, Regensburg (DE)

Correspondence Address: COHEN, PONTANI, LIEBERMAN & PAVANE, 551 FIFTH AVENUE, SUITE 1210, NEW YORK, NY, 10176, US

(21) Appl. No.: 10/541,298

(22) PCT Filed: Dec. 18, 2003
(86) PCT No.: PCT/DE03/04197

§ 371 Date: Jan. 17, 2006

(30) Foreign Application Priority Data
Dec. 30, 2002 (DE) 102614261
Feb. 18, 2003 (DE) 103067795

(51) Int. Cl. C23F 1/00; H01L 33/00

(52) U.S. Cl. 216/41; 257/103

(57) ABSTRACT

A method for roughening a surface of a body (1), having the following steps of: coating the surface with a mask layer (2), applying preformed mask bodies (3) on the mask layer (2), etching through the mask layer (2) at locations not covered by mask bodies (3), and etching the body (1) at locations of its surface that are free of the mask layer (2).

The invention relates to a method for roughening a surface of a body, the roughening being effected by means of etching.

Roughened surfaces may be used advantageously particularly in connection with light emitting diodes (LED). The reason for this is the coupling-out of light from the semiconductor body which forms the basis for the LED. A high jump in refractive index is generally present in this case, the refractive index of the semiconductor material typically being n=3.5. The resin surrounding the semiconductor body has a refractive index that is typically n=1.5. This results in a high jump in refractive index for radiation emerging from the semiconductor body. This results in a small angle of total reflection with respect to the surrounding resin of approximately 26°. This angle of total reflection has the effect that only a fraction of the light generated in the semiconductor body can be coupled out. In the simple cubic shape of the LED that is typically used in production, a beam that is not emitted in the approximately 26° wide coupling-out cone remains trapped in the semiconductor crystal since its angle with respect to the normal to the surface cannot be altered even by multiple reflections. Consequently, the light beam will be lost sooner or later by absorption primarily in the region of the contact, the active zone or else in the substrate.

A roughness of the surface of the semiconductor body may then advantageously be used for scattering beams which propagate outside the coupling-out cone into such a cone. This is of interest primarily in the case of LED chips with a transparent substrate or an effective mirror below the active zone, in particular also in the case of thin-film LEDs. These advantages also apply to organic LEDs.

The document U.S. Pat. No. 3,739,217 discloses that the coupling-out of light from gallium phosphite crystals can be improved by roughening the surface.

The document R. Windisch et al., “40% Efficient Thin-Film Surface-Textured Light-Emitting Diodes by Optimization of Natural Lithography”, IEEE Transactions on Electron Devices, Vol. 47, No. 7, 2000, p 1492-1498, discloses roughening semiconductor bodies based on aluminum gallium arsenide in order to improve the coupling-out of light from the semiconductor body. A roughening method that is described below is used in this case. Balls made of polystyrene are applied to the surface of the semiconductor body. Said balls may be prepared in a monolayer on a water surface, for example, and then be transferred to the surface of the semiconductor body by immersion. After the water has dried, the balls adhere on the surface of the body. The surface is subsequently dry-etched, as a result of which pillars remain at the locations of the balls and the space between the pillars has been etched away from the semiconductor body by the dry etching process.

This known method for roughening the surface of a body has the disadvantage that it is not suitable for application in the case of semiconductor bodies made of the material aluminum gallium indium phosphite or aluminum gallium indium nitride. The reason for this is that the dry etching methods used have an excessively low selectivity with regard to the polystyrene balls. This means that the semiconductor body is etched only very slowly in comparison with the balls, for which reason the balls serving as an etching mask will already have disappeared at a very early point in time in the etching process when only a very small structure depth has been etched into the surface of the body. The consequence of this is that the required ratio of etching depth to structure width of 0.25 to 5 cannot be achieved. This ratio is required in order to efficiently improve the coupling-out of light from the semiconductor body.

It is an object of the present invention to specify a method for roughening a surface of a body which is suitable for many different materials.

This object is achieved by means of a method according to patent claim 1. Advantageous refinements of the method can be gathered from the dependent patent claims.

The invention makes use of the fundamental idea according to which the problem of the selectivity of the etching methods used can be alleviated by additionally using a further auxiliary mask besides the masking by the small polystyrene balls. Said auxiliary mask is composed of a material which is both different from the material of the body to be etched and different from the material of the balls. With the aid of this additional mask, the etching process can be subdivided into two steps, in a first step the structure of the balls arranged on the surface being transferred into the auxiliary mask. In a second step, the structure of the auxiliary mask is then transferred into the surface of the body to be etched.

By virtue of the fact that, in addition to the balls, a further material is also involved as a mask, a much larger selection of material combinations is available, in which case the processes can be optimized with regard to an increased selectivity between the mask material and the material to be etched. By way of example, there are etching methods which are unsuitable for a specific material combination of balls and body to be etched. However, these etching methods can be used for carrying out the first etching step according to the now two-step etching method. Moreover, it is now possible to etch the body to be roughened by means of a method which need not necessarily be selective with respect to the balls situated on the surface. Rather, it suffices for the second etching method to have a high selectivity with regard to the material of the auxiliary mask, on the one hand, and with regard to the body to be etched, on the other hand.

A method for roughening a surface of a body is specified, which comprises the following steps:

In a first step, the surface of the body is coated with a mask layer.

In a subsequent step, preformed mask bodies are applied to the mask layer.

In a subsequent step, the mask layer is etched through, to be precise at locations not covered by mask bodies.

In a subsequent step, the body is etched at locations of its surface which have been freed of the mask layer.

The method has the advantage that by introducing a further etching mask, the etching operation can be split into two steps, an etching method which etches the body highly selectively with respect to the preformed mask bodies no longer being required. Rather, through variation of the materials of the mask bodies and the mask layer, a broad spectrum of possible etching methods can be rendered suitable, that is to say that a broader spectrum of etching methods is taken into consideration for the etching operation.

In one embodiment of the method, the body contains aluminum gallium indium phosphite (AlGaInP). This semiconductor material is advantageously used for light emitting diodes which emit in the red or blue spectral range. This semiconductor material is optionally deposited on silicon carbide or on a gallium arsenide substrate.

In another advantageous embodiment of the method, the body contains aluminum gallium indium nitride (AlGaInN). This material is also particularly well suited to light emitting diodes in the red or blue spectral range.

In one embodiment of the method, a mask layer comprising a dielectric is applied. Examples of appropriate dielectrics are Si_{X}N_{Y}, for example Si₃N₄, SiON, SiO₂, Al₂O₃ and also further similar materials. Dielectrics are thus preferably used for the mask layer. However, other materials may also be suitable for the mask layer. All that is crucial is that the material of the mask layer can be etched selectively with respect to the mask bodies by means of an etching process and that the body can be etched selectively with respect to the mask layer by means of a further etching process different therefrom.

In one embodiment, balls made of polystyrene may be used for the preformed mask bodies. On account of their good chemical stability and on account of the possibility of being able to produce polystyrene balls in large numbers using simple and inexpensive means, said polystyrene balls are suitable as mask bodies in particular for the method described here.

In this case, the mask bodies may be applied as monolayer on the surface of the mask layer both in the form of a random arrangement and in the form of a regular arrangement.

In an advantageous embodiment of the method, the etching steps are carried out by means of a dry etching method. Examples of appropriate methods are methods such as reactive ion etching (RIE), ion beam etching (IBE) and also chemical assisted ion beam etching (CAIBE), etc.

By way of example, consideration is also given to using an inductively coupled plasma etching method (ICP) as dry etching method.

In the case of the present method, dry etching methods have the advantage that the use of liquids is dispensed with, which increases the local stability of the mask bodies since no flows in a liquid can occur.

In an advantageous refinement of the method, the latter is carried out in such a way that structures remain in the surface of the body, for the width b of which structures in relation to the etching depth t the following holds true:
0.1<t/b<10.

The method is preferably carried out in such a way that the following holds true:
0.25<t/b<5.

Such a depth-to-width ratio is particularly advantageous in order to improve the scattering at the surface of optical semiconductor crystals in order to improve the coupling-out of light from the crystal toward the outside.

The aforementioned etching-depth-to-width ratio can be achieved by suitable selection of the etching processes and also the extent and the material of the mask bodies.

In one variant of the method described here, the mask bodies are removed immediately after etching through the mask layer. In another variant, the mask bodies are left on the surface of the mask layer in order to serve as an additional etching mask there during the second etching process. After the end of the etching processes, the mask layer may be removed or alternatively remain on the surface of the body.

The method is advantageously carried out in such a way that the etching depth into the body is between 50 and 100 nm. Such an etching depth may be achieved by using an etching process with a suitable selectivity between the mask layer and the body to be etched. Moreover, the etching duration must also be chosen suitably in order to achieve the desired etching depth.

Preferably, in the case of the method described here, the mask layer is applied with a thickness of between 10 and 100 nm. A minimum thickness for the mask layer is necessary in this case since otherwise it cannot serve reliably as masking of the body. However, a specific maximum thickness should in turn not be exceeded either, in order that the time duration required for etching through the mask layer is kept within limits.

In order to achieve the ratio of etching depth and structure width that has already been described further above, it is advantageous to use mask bodies whose lateral extent on the mask layer is between 150 and 300 nm.

The method described here advantageously uses, for the first etching step, a process having a poor selectivity with regard to the mask bodies and the body to be roughened. In this case, it is even conceivable to use a process which etches the mask bodies to a greater degree than the body to be roughened, but only for the case where the etching process again has a suitable selectivity with regard to the mask layer.

By way of example, etching through the mask layer may be effected by means of an installation for reactive ion etching.

A fluorine process may advantageously be employed in this case, a gas mixture of CHF₃ and argon being used. A standard RIE installation with a parallel plate reactor is usually used in this case.

The second etching step may be carried out for example by means of an ICP installation, a mixture of CH₄ and H₂ being used as etching gas.

Furthermore, an optoelectronic component having a semiconductor body is also specified. Said semiconductor body contains aluminum gallium indium phosphite or aluminum gallium indium nitride. Furthermore, the surface of the body is patterned, the following holding true for the width of the structures in comparison with the depth of the structures or the etching depth: 0.25<t/b<5. Furthermore, the same component is specified but the semiconductor body contains aluminum gallium indium nitride instead of aluminum gallium indium phosphite. Such optoelectronic components, for example LEDs, can be produced for the first time with the aid of the method presented here. The methods disclosed in the prior art are not suitable for producing the ratio of t to b described here.

In this case, the term “structures” is to be understood as what projects from the surface of the semiconductor body after the etching thereof. The width of these structures might be for example the width of the pillars or towers described in the document R. Windisch et al., “40% Efficient Thin-Film Surface-Textured Light-Emitting Diodes by Optimization of Natural Lithography”, IEEE Transactions on Electron Devices, Vol. 47, No. 7, 2000, p 1492-1498.

The invention is explained in more detail below with reference to an exemplary embodiment and the associated figures:

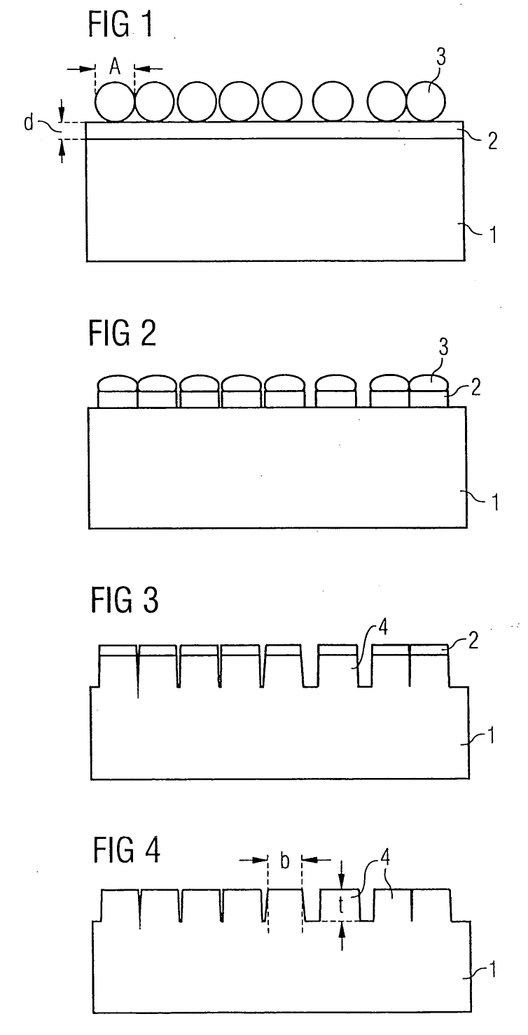

FIG. 1 shows a body to be etched, to which a mask layer and mask bodies are applied.

FIG. 2 shows the body from FIG. 1 after the first etching step.

FIG. 3 shows the body from FIG. 2 after the second etching step.

FIG. 4 shows the body from FIG. 3 after the removal of the mask layer.

It is pointed out that all the FIGS. 1 to 4 illustrate a schematic cross-sectional view. It is furthermore pointed out that identical reference symbols identify identical elements or at least elements having an identical or similar function.

FIG. 1 shows a body 1, which may be a semiconductor body for example. A mask layer 2 is applied on a surface of the body 1. The mask layer 2 advantageously has a thickness d of between 10 and 100 nm.

Mask bodies 3 are applied to the mask layer 2, which mask bodies, in the special case considered here, firstly form a monolayer and secondly have the form of balls. The lateral extent A of the balls is in this case between 150 and 300 nm. However, it is also possible to use mask bodies with other forms and other suitable materials.

FIG. 2 shows the appearance of the arrangement according to FIG. 1 after the first etching step. The mask layer 2 has been etched through at the locations at which it is not covered by mask bodies 3. A perforated mask layer 2 accordingly results, mask bodies 3 still being arranged on the surface of the mask layer 2. However, the mask bodies 3 have been reduced in volume somewhat compared with the illustration in FIG. 1 as a result of generally unavoidable etchings. This results from the fact that almost all etching methods which are used for etching the mask layer 2 also always, and albeit even only to a very small extent, etch the mask bodies 3.

The mask bodies 3 on the surface of the mask layer 2 are subsequently removed. However, this step is not mandatory; rather, it is also possible to leave the mask bodies 3 on the surface of the mask layer 2.

FIG. 3 shows the state of the arrangement according to FIG. 1 where, however, the second etching step has already taken place. This means that the surface of the body 1 already has structures 4. The residues of the mask layer 2 have still remained on the surface of the structures 4.

FIG. 4 shows the arrangement according to FIG. 3 after the removal of the mask layer 2. The result is structures 4 whose width b in relation to the etching depth t satisfies the following condition:
0.25<t/b<5

The structures 4 may have the form of cylindrical turrets, by way of example.

The structures 4 may either be positioned regularly along a grid defined in the front end by the arrangement of the mask bodies 3. However, the structures 4 may also be distributed randomly over the surface of the body 1.

1. A method for roughening a surface of a body (1), having the following steps of:
a) coating the surface with a mask layer (2)
b) applying preformed mask bodies (3) on the mask layer (2)
c) etching through the mask layer (2) at locations not covered by mask bodies (3)
d) etching the body (1) at locations of its surface that are free of the mask layer (2).

2. The method as claimed in claim 1, the body (1) containing aluminum gallium indium phosphite.

3. The method as claimed in claim 1, the body (1) containing aluminum gallium indium nitride.

4. The method as claimed in claim 1, the mask layer (2) comprising a dielectric.

5. The method as claimed in claim 1, balls made of polystyrene being used as preformed mask bodies (3).

6. The method as claimed in claim 1, the etching steps being carried out by means of a dry etching method.

7. The method as claimed in claim 1, the method being carried out in such a way that structures (4) remain in the surface of the body (1), for the width (b) of which structures in relation to the etching depth (t) the following holds true: 0.1<t/b<10.

8. The method as claimed in claim 1, the method being carried out in such a way that structures (4) remain in the surface of the body (1), for the width (b) of which structures in relation to the etching depth (t) the following holds true: 0.25<t/b<5.

9. The method as claimed in claim 1, the residues of the mask body (3) being removed from the mask layer (2) immediately after step c).

10. The method as claimed in claim 1, the etching depth (t) in the body (1) being between 50 and 100 nm.

11. The method as claimed in claim 1, the mask layer (2) being applied with a thickness (d) of between 10 and 100 nm.

12. The method as claimed in claim 1, the mask bodies (3), on the mask layer (2), having a lateral extent (A) of between 150 and 300 nm.

13. The method as claimed in claim 1, the first etching step being effected by means of a process step which etches the mask bodies (3) to a greater degree than the body (1).

14. The method as claimed in claim 1, the etching through the mask layer (2) being effected by means of an installation for reactive ion etching.

15. The method as claimed in claim 14, a mixture of CHF₃ and Ar being used as etching gas.

16. The method as claimed in claim 1, the body (1) being etched by means of an installation suitable for an inductively coupled plasma.

17. The method as claimed in claim 16, a mixture of CH₄ and H₂ being used as etching gas.

18. (canceled)

19. (canceled)

20. An optoelectronic component, comprising:
a semiconductor body containing aluminum gallium indium phosphate and having a surface that is patterned with structures;
wherein each of said structures has a ratio of depth (t) to width (b) that is in accordance with the relationship 0.1<t/b<10.

21. The optoelectronic component in claim 20, wherein each of said structures has a ratio of depth (t) to width (b) that is in accordance with the relationship 0.25<t/b<5.

22. An optoelectronic component, comprising:
a semiconductor body containing aluminum gallium indium nitride and having a surface that is patterned with structures;
wherein each of said structures has a ratio of depth (t) to width (b) that is in accordance with the relationship 0.1<t/b<10.

23. The optoelectronic component in claim 22, wherein each of said structures has a ratio of depth (t) to width (b) that is in accordance with the relationship 0.25<t/b<5.
